(19) United States
(12) Patent Application Publication
(10) Pub. No.: US 2009/0230988 A1
(43) Pub. Date: Sep. 17, 2009

(54) ELECTRONIC DEVICE HAVING LOGIC CIRCUITRY AND METHOD FOR DESIGNING LOGIC CIRCUITRY

(75) Inventors: Andre Krijn Nieuwland, Eindhoven (NL); Theodorus Gerardus Albertus Heijmen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/720,213

(22) PCT Filed: Nov. 28, 2005
(86) PCT No.: PCT/IB05/53932

§ 371 Date: May 25, 2007

(30) Foreign Application Priority Data
Dec. 1, 2004 (EP) 04106203.5

(51) Int. Cl. H03K 19/007; G06F 17/50

(52) U.S. Cl. 326/9; 716/1

(57) ABSTRACT

An electronic device with logic circuitry (LC) is provided. The logic circuitry (LC) comprises at least one electronic unit (EU), in particular one logic gate with a first electronic component (EC1) for performing logic operations; and at least one second electronic component (EC2) for improving the soft-error sensitivity of the logic circuitry (LC). The first and the second electronic component (EC1, EC2) are implemented with substantially the same logical function. The second electronic component (EC2) is redundant. In addition, the inputs of the first and the second electronic component (EC1, E2) are coupled and the outputs of the first and the second electronic component (EC1, E2) are coupled, respectively.

The invention relates to an electronic device having logic circuitry and a method for designing logic circuitry.

The protection of integrated circuits (ICs) from soft errors is becoming an increasingly important issue regarding the reliability of state-of-the-art submicron IC technologies. When a neutron or an alpha particle strikes a semiconductor device, it creates charges in the form of electron-hole pairs. Part of the deposited charges is collected by pn-junctions near the impact location, which results in a transient current pulse. If the struck junction is the drain of a transistor in the OFF-state, the current pulse disturbs the voltage level of the circuit node connected to this drain junction. If the circuit is a memory cell, such as an SRAM cell, a latch, or a flip-flop, the disturbance can lead to a change in the state of the circuit (bit flip). Such a bit flip, caused by the impact of a neutron or an alpha particle, is called a single-event upset (SEU) or a soft error. The original data that was stored in the cell is lost, but the device is not permanently damaged. The protection of an IC from soft errors is important because a soft error changes the state of the system in which it occurs.

In addition, combinatorial logic is contributing more and more to the overall soft error rate. If the struck circuit node is in a logic gate, the disturbed node voltage can result in a voltage (or current) pulse that propagates through the combinatorial logic. Such a pulse is called a single-event transient (SET). Eventually, the SET may result in the storage of an erroneous data bit in a memory cell of the system. Also such a corrupted data bit is called a soft error.

One approach to improve the soft error rate is to use so-called radiation-hardened (memory) cells, such as hardened SRAM cells or flip-flops. Radiation hardening can be done by applying special options in the IC processing, but these are expensive and not always available. Alternatively, the circuit design of the memory element can be modified, for example by adding extra resistor or capacitor elements. However, this results in an overhead in terms of area, timing and/or power dissipation.

In “Cost-Effective Approach for Reducing Soft Error Failure Rate in Logic Circuits”, by Mohanram and Touba, ITC 2003, pp 893-901, September 30-October 2, Charlotte, N.C., USA an approach is described to reduce the effects of soft error failure in logic circuits. Here, only those nodes in the circuit are targeted which have the highest soft error susceptibility. The output of the circuitry is monitored by concurrent error detection CED in order to detect any occurrences of errors. Once an error is detected, the system can repair the failure. However, CED will lead to a very high overhead in terms of power dissipation, area and timing. The approach selects the nodes in the logic circuit that are most sensitive to the occurrence of soft error failure. The probability that a single-event transient SET is latched depends on the logic function that is implemented and on the distribution of the input data. In addition, the sensitivity of a node is affected by the node capacitance and by the sizes of the gates driving the node. Moreover, the logic depth between a circuit node and a memory cell is also an indicator of the probability that a disturbance of the node voltage will result in a soft error in the memory element.

Typically, the concurrent error detection CED uses error-detecting codes such as parity, duplication and compare or the like. Checkers are employed to monitor the output in order to determine an occurrence of an error. Often a cluster of nodes near the primary inputs of a logic circuit is selected and duplicated. If a single-event transient occurs and propagates through the logic such a single-event transient SET will be detected by the concurrent error detection CED. Accordingly, after selecting those nodes that are most susceptible to soft errors, these nodes are duplicated to detect the occurrence of soft errors.

However, the duplication of some of the nodes in the logic circuitry may lead to an overhead with regard to power dissipation, area (30-200%) and timing which may not be acceptable for mainstream applications. In addition, the extra circuitry that is added to enable concurrent error detection may also be subject to soft errors and may further degrade the timing behavior.

It is an object of the invention to provide an electronic device that is less susceptible to soft errors without an extensive overhead, such as concurrent error detection (and correction) circuitry.

This object is solved by an electronic circuit according to claim 1 and a method for designing logic circuitry according to claim 7.

Therefore, an electronic device with logic circuitry is provided. The logic circuitry comprises at least one electronic unit, in particular one logic gate with a first electronic component for performing logic operations; and at least one second electronic component for improving the soft-error sensitivity of the logic circuitry. The first and the second electronic component are implemented with substantially the same logical function. The second electronic component is redundant. In addition, the inputs of the first and the second electronic component are coupled and the outputs of the first and the second electronic component are coupled, respectively.

Accordingly, no additional logic gates are required for combining the outputs of the additional redundant electronic components for error correction and detection or to logically merge functional parts. Furthermore, the additional electronic components do not need to be radiation-hard electronic components but the additional electronic components can be selected from standard-cell libraries. As extra circuitry for error correction coding is not required, the necessary area overhead will be small as well as its impact on timing.

According to a further aspect of the invention, the first and second electronic components are being at least partially physically separated. Therefore, the probability that a circuit in the first electronic component and a circuit node in the second electronic component are disturbed simultaneously is significantly reduced without reducing the overall drive strength of the electronic components.

According to still a further aspect of the invention, the first and second electronic component is at least one of a logical gate, a gate of a transistor and a transistor. Therefore, the duplication of the electronic components can be performed on logical gate basis and/or on a transistor basis.

The invention also relates a method for designing a logic circuitry. A plurality of electronic units each comprising a first electronic component for performing logic operations is provided. At least one second electronic component in at least one of the plurality of electronic units is provided for improving the soft-error sensitivity of the logic circuitry. The second electronic component is selected such that the first and second electronic component substantially implement the same logical function, and the second electronic component is redundant. The outputs and the inputs of the first and second electronic component are mutually coupled, respectively.

The invention is based on the idea that the soft error sensitivity of an electronic device is improved by adding additional (optionally physically separated) redundant electronic elements like gates sharing the same inputs and outputs, i.e., being arranged in parallel. This usually violates design rules as the outputs of separated gates are directly connected. However, as these electronic elements are logically equivalent a real violation of the design rules will not occur, as the outputs of the electronic elements will drive the output to the same value. The provision of additional redundant electronic elements or components may be applied to the internal circuitry of a cell or may be applied to parts of a logic tree within a logic circuitry. In case the same drive strength is realized by two components rather than a single (larger) component, the SET is reduced since the only one of the two components will be affected at the same time.

These and other aspects of the invention are apparent from and will be elucidated with reference to the embodiments described hereinafter.

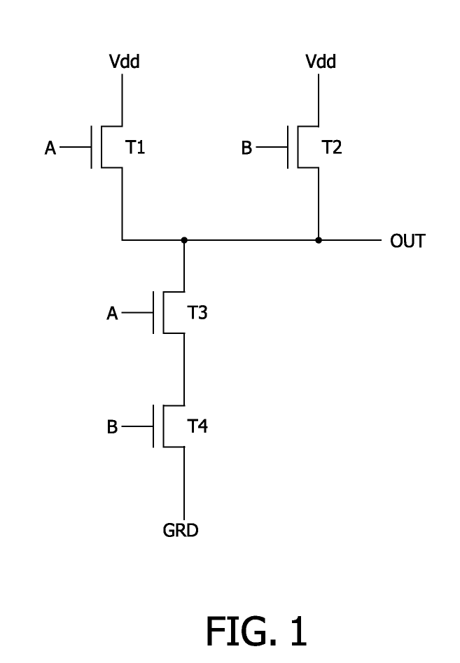

FIG. 1 shows a circuit diagram of an electronic unit,

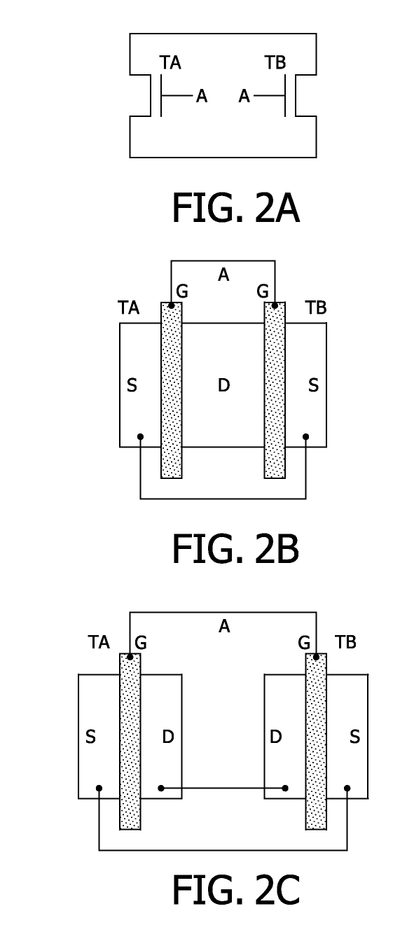

FIG. 2a shows a circuit diagram of a double transistor of FIG. 1,

FIG. 2b shows a layout of a double transistor of FIG. 2a according to a first embodiment,

FIG. 2c shows a layout of a double transistor of FIG. 2a according to a second embodiment,

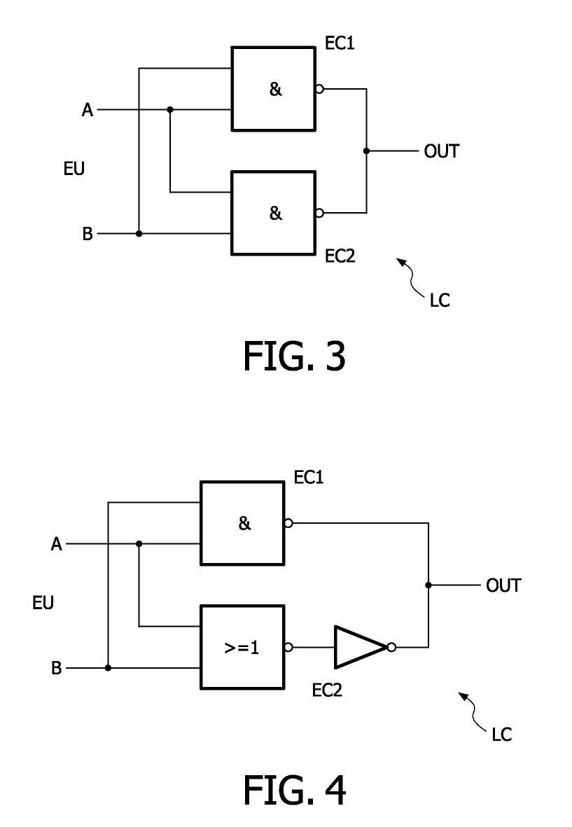

FIG. 3 shows a circuit diagram of a third embodiment, and

FIG. 4 shows a circuit diagram of a fourth embodiment.

FIG. 1 shows a circuit diagram of an electronic unit, in particular a NAND gate, being a logic gate that is generally applied in IC design. In total four transistors T1-T4 are shown. A first and second P-type transistor T1, T2 are arranged in parallel with their drains connected to the supply voltage V_{dd} and their source connected to an output terminal OUT. The third and fourth transistors T3, T4 are connected in series between the output terminal and ground. In particular, the third transistor T3 (N-type transistor) is connected with its drain to the output terminal OUT and with its source to the drain of the fourth transistor T4 (also a N-type transistor). The first transistor T1 and the second transistor T2 are less critical to the occurrence of a single-event transient SET because these two transistors are connected in parallel such that a compensation effect with regard to the sensitivity to soft errors occurs. In addition, P-type transistors are less sensitive to single-event transients SET than N-type transistors. This is because in N-type transistors the SET is caused by the collection of electrons in the drain, while in P-type transistors, the SET corresponds to the collection of holes. As electrons are more mobile than holes, single-event transients SET in N-type transistors generally have higher amplitudes and large pulse widths than in P-type transistors.

The drain of the third transistor T3 (N-type transistor) is the most critical part in the circuit diagram of FIG. 1 because it is a N-type transistor. Furthermore, it is directly connected to the output, which implies that an SET generated in the drain of T3 directly affects the output.

The fourth transistor T4 (N-type transistor) is substantially subject to the same problems as the third transistor T3. However, the fourth transistor T4 is coupled in series to the third transistor T3. Therefore, an SET generated in the drain of T4 can only affect the output OUT if transistor T3 is conducting. Furthermore, if T3 conducts, the resistance of T3 will attenuate an SET generated in the drain of T4 before it reaches the output OUT.

FIG. 2a shows a circuit diagram of a duplicated or double transistor as shown in FIG. 1. Here, the third transistor T3 is duplicated while the inputs and outputs are tied or coupled together, respectively. The duplicating of the third transistor T3 is performed in order to reduce the sensitivity to single-event transients SET and therefore to reduce the contribution of the circuit to the soft error rate (SER) of the system.

FIG. 2b shows a layout of the double transistor TA, TB according to FIG. 2a according to the first embodiment. Here, the gates G have been separated to reduce their sensitivity to the SET. Here, the drain area D is still connected, the layout of FIG. 2b is advantageous with regard to a minimum drain area leading to reduced costs and a minimum area on a chip. However, if the gates are designed too small or to close together, a particle impact may influence both of the gates and induce respective currents to both channels arranged beneath the gates.

FIG. 2c shows a layout of a double transistor TA, TB according to FIG. 2a according to the second embodiment. Here, the drain areas D have been separated as compared to the layout of FIG. 2b. This is in particular advantageous, as an impact of an ionizing particle will in general not result in simultaneous SETs in both transistors if the physical separation of the transistors is sufficient. This effect becomes more important if the size of the transistors is reduced. However, the duplication of the transistor TA, TB will result in a larger area, leading to increased costs.

Although the transistor TA, TB is duplicated according to FIG. 2c, the drain-size is of the same area according to FIG. 2b. Whereas the transistor in the OFF-state is sensitive, the sensitivity remains the same. In this case, it is better to have the drain-size only half this size and the drive strength of the partially duplicated transistor the same as the original single-transistor.

FIG. 3 shows the circuit diagram of a third embodiment of the invention. Here, a NAND-gate has been duplicated and, on the one hand, the inputs A and B are coupled together and, on the other hand, the outputs of the two individual NAND-gates are coupled together. In other words, the two NAND-gates are arranged in parallel. The provision of the second NAND-gate will decrease the soft error sensitivity of the overall electronic unit, as any SET occurring at the first NAND will not influence the performance of the second NAND. Therefore, an SET generated in one NAND-gate will be largely compensated by the operation of the other NAND-gate.

FIG. 4 shows a circuit diagram according to a fourth embodiment. In contrast to the second embodiment according to FIG. 3, here the first NAND-gate is not duplicated identically but duplicated with an identical logical function, in this particular case by a NOR-gate with an inverter at its output. Accordingly, the duplication of the gates does not necessarily have to lead to an identical duplication but also other equivalent circuits are possible as long as the delay of the first NAND-gate and the equivalent duplicated circuit is matched. With the circuit arrangement according to FIG. 4 the propagation of an SET from within the NAND-gate will be strongly attenuated by the provision of the NOR-gate and the inverter in parallel to the NAND-gate. In addition, any disturbance of data at the inputs A and B of the electronic unit will be suppressed at the output of the electronic unit, provided that the two do not have exactly the same propagation delays

According to the first to fourth embodiments of the invention, the sensitivity to radiation-induced soft errors of a logic gate is reduced by increasing the drive strength of the most sensitive electronic components by inserting additional redundant and physically separated electronic components. The inserted additional electronic component can be an additional gate or an additional transistor. The input and output terminals are mutually coupled together such that the redundant additional electronic components are arranged in parallel, which improves the ability to suppress current pulses. In case the same drive strength is realized by two components rather than a single (larger) component, the SET is reduced since the only one of the two components will be affected at the same time. If two NAND-gates (of minimum size) are driving the input of a flip-flop, a current pulse as induced at the output of one of the NAND-gates will have reduced amplitude due to the combined driving ability of the two NAND-gates. In such an arrangement, the probability of a simultaneous SET in both electronic components is very small if the physical separation between the two electronic components is sufficiently large.

The second NAND-gate is preferably arranged in parallel to the first NAND-gate, i.e. the inputs are shared and the outputs of the first and second NAND-gates are tied together.

Preferably, the second NAND-gate is redundant and is substantially of the same size and comprises the same characteristics as the first NAND-gate. Accordingly, extra drive strength is provided for the most sensitive node, namely the output, such that an SET induced by the impact of an ionizing particle is attenuated. In addition, the larger output capacitance is also stabilizing the output of the electronic units.

The above does not only apply to logic gates but also to internals of any cells or electronic circuits, where additional gates, latches, flip-flops or the like can be arranged in parallel in order to reduce the soft error rate sensitivity of the logic circuit.

Furthermore, parts of a logic tree in a circuit can be doubled such that redundant components are placed in parallel. Here, the additional redundant units do not necessarily have to be exactly the same as the original units that are to be protected by the second additional redundant units. The implementation of the second redundant units may be different from the first units as long as their logical function is the same as those of the original units. In addition, the delay of both units should match sufficiently to ensure correct functioning of the circuit. Such an arrangement is especially advantageous with regard to the reduction of glitch propagation. For example, in the case of a NAND-gate with “A=1, B=1” as its inputs a glitch (1→0) at the input will propagate through the gate. However, a NOR-gate with an inverter, as shown in FIG. 4, will basically implement the same logical function but will not propagate a downward glitch on a single input when the input combination is “A=1, B=1”.

It should be especially noted that an actual connection of two outputs generates a typical design rule violation for standard IC design software that will be detected by a layout-versus-schematic (LVS) check. However, according to the invention this is advantageous although the specific design rules are intentionally violated. No specific electrical problems are expected as the outputs of the first and second units will always drive in the same direction and conflicts like glitches are only of temporary nature.

It should be noted, it can be very effective to selectively increase drive strengths of transistors of a logic gate: E.g. increasing the drive strengths of the p-type transistors T1 and T2 in the NAND-gate of FIG. 1, will significantly reduce the contribution to the soft error rate of the n-type-transistors T3 and T4. For this selective drive strength enhancement, the transistor implementation of FIG. 2B is preferred, as in this way you have the maximum drive strength with a minimum (sensitive) drain area.

Note that when using the scheme of FIG. 2B for T1 and T2 of FIG. 1, the source on the right hand side can be shared by both T1 and T2, whereas the drains of both transistors are relatively small and physically separated. This partial duplication would be a very efficient way of reducing the (peak) Soft Error sensitivity of a cell.

According to a fifth embodiment of the invention, which may be based on any of the first to fourth embodiment, an algorithm is provided to automatically identify those cells in an RTL level circuit description that are critical with respect to induced single-event transients (SETs). Those cells that are considered to be critical are amended by the insertion of redundant cells parallel to the identified cell to reduce the soft error sensitivity of the circuit.

Here, an SE sensitivity metric per cell (the metric depends on the layout of the cell and on the technology) is used to select the critical cells. The probability that SETs originating from any of these cells propagate to the output of the circuit is calculated. The cells that contribute most to the soft error rate (SER) at the output are the SER critical cells. These cells are than automatically replaced by hardened cells, larger cells or duplicated cells (multiple instances of the same cells which share physically the same inputs and outputs, as described according to the above embodiments). The replacement of cells by protected cells is performed until a specified failure rate (error probability) is met.

This leads to a reduced SER sensitivity of the circuit in a very cost-effective way since only the more critical nodes are protected and not more nodes are protected than required for a certain specified failure rate. Preferably, only those gates are modified that have the largest contribution to the SER at system level, and the modification (adding redundant gates) is stopped as soon as the system's (SE) failure rate is met. The contribution of the individual gates depends on the structure and topology (implementation) of the logic function.

It is a tedious job for a designer to go through the whole design, analyze the contribution of each gate, and implement a suitable fix on the necessary positions. A tool (or algorithm) to do this for the designer is desirable.

A structured way of circuit analysis is used. The most exact results are obtained by full input value analysis, i.e., all possible input vectors are applied to a logic circuit (taking the likelihood of their occurrence into account), and all the nodes on the logical path to the output are analyzed and their contribution to the output soft error rate (SER) is computed. Preferably, the input data are propagated from input to output, after which the SE analysis takes place backwards from the output towards the input, or alternatively, the soft error sensitivity value of certain nodes are carried forward while performing the netlist analysis. In general, the further away from the output, the lower the contribution to the output soft error rate due to the electrical masking effect (every gate acts more or less as a low-pass filter, which reduces the probability of small transients to arrive at the output). Only paths that are logically enabled have to be observed. For example, a positive glitch (sudden ‘one’) at the input of an AND gate of which the other input is ‘zero’ will not pass that gate and that branch will not contribute to the output SER for that input combination. It is an advantage of the invention that in this way the topological structure (re-convergent paths) can be dealt with. A further advantage is that not the complete circuit has to be analyzed at once, but that the algorithm can operate on sub-circuits separately. This reduces complexity and speeds up the run-time. The run-time of the algorithm can be further reduced (at the cost of slightly reduced accuracy) by applying heuristics rather than full netlist analysis, and/or by reducing the input vector set by selecting the statistically more relevant vectors or by selecting a representative set of vectors.

For each enabled logical path and for each node on that path, the probability of a SET to be generated at that node and the probability that that specific SET can travel to the output can be calculated, for example, with the use of a compact model.

This approach can be implemented as a software tool that performs this analysis on RTL level netlists (logical blocks), and/or on gate level netlists (either with our without routing information) when more information on the drive strength of the gates is available.

This can be applied on all combinatorial logic circuits in digital IC designs for which soft errors are considered as a problem. This will be first for automotive and medical applications, for ICs for compute servers, and also for the larger digital systems. With progress in technology, soft errors will be also more important for the smaller designs, as newer technologies are inherently more sensitive to soft errors.

The main advantage of the above-described embodiments is that only little additional logic, i.e., only a limited number of additional logic gates, is required to reduce the soft error rate of the electronic devices as only the most sensitive gates or nodes are protected. Here, the last logical levels are considered the most important as these are typically closest to flip-flop inputs and any SET induced by the impact of ionizing particles can propagate immediately through the electronic units. Furthermore, electronic units arranged earlier in the logic tree of the logic circuitry have a higher probability of logical masking, i.e., the probability that the struck node is in a path that is not logically enabled is higher. In contrast to the concurrent error detection methods described above, no additional logic circuitry is required for combining the outputs of the concurrent error detection units and the protected units. Furthermore, no additional circuitry is needed for the error correction and detection and no circuitry is needed to logically merge the two functional paths. This is in particular advantageous as this circuitry would be sensitive to a single-event upset as well.

An additional advantage is that standard gates from regular standard-cell libraries can be used instead of dedicated radiation-hardened electronic units.

The principles of the invention described above may also be used for any internals of flip-flops or other cells or electronic units. The reduction of the soft error rate as described above cannot be obtained by a decoding/correcting circuitry as such a circuitry itself is also sensitive with regard to an impact of an ionizing particle. With the arrangement described above, even such circuitry can be protected with only a very small area overhead.

Furthermore, by physically separating the electronic units of electronic components such as the gates, i.e., by scrambling the electronic units, the possibility of simultaneous SETs will be significantly reduced. An incident particle, particularly a neutron, can induce more than one SET as the impact may result in more than one ionizing particle or because deposited charges are collected by multiple junctions. By physically separating the electronic components, the probability that both the original and the redundant component are simultaneously subject to an SET can be reduced to practically zero. If an SET is induced in one of the components, the other one will stabilize the output node. In this way, the usage of redundant logic gates, provided that they are scrambled, results in an improved soft-error sensitivity, as compared to one larger gate with an equal drive strength. The principles of the invention described above may become more important for newer technologies with even smaller dimensions as feature sizes become small in comparison with the area over which electron-hole pairs are generated by a single impact. In the case of a large transistor, an induced SET can have a high amplitude and a large pulse width due to the relatively large collection efficiency of the transistor. However, a small transistor will have a much lower collection efficiency because charge collection efficiency is decreasing with decreasing area of the drain junction. Accordingly, an induced SET will also be narrower and contain less charge. As only one of the transistors is affected at a time, the principles of the invention described above offer a scalable way to deal with soft errors in future silicon technology generations.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

Furthermore, any reference signs in the claims shall not be construed as limiting the scope of the claims.

1. Electronic device comprising:
logic circuitry (LC) having
at least one electronic unit (EU) comprising a first electronic component (EC1) for performing logic operations; and at least one second electronic component (EC2) for improving the soft-error sensitivity of the logic circuitry (LC);
wherein the first and second electronic component (EC1, EC2) implement substantially the same logical function,
wherein said first and second electronic component (EC1, EC2) each comprise inputs and outputs being mutually coupled.

2. Electronic device according to claim 1,
wherein the first and second electronic components (EC1, EC2) being at least partially physically separated.

3. Electronic device according to claim 1,
wherein the first and second electronic component (EC1, EC2) being at least one of a logical gate, a gate of a transistor and a transistor.

4. Electronic device according to claim 1,
wherein a delay of the first and second electronic components (EC1, EC2) are matched.

5. Electronic device according to claim 3,
wherein the electronic unit is implemented as a NAND-gate having a first and second transistors (T1, T2) being P-type transistors and a third and fourth transistor (T3, T4) being N-type transistors (T3, T4),
wherein the first and second transistors (T1, T2) comprise an increased drive strength.

6. Electronic device according to claim 5, wherein
at least one of the first and second transistors (T1, T2) is duplicated by replacing it with two transistors (TA, TB),
wherein the drains (D) of the two transistors (TA, TB) are coupled together while the gates (G) and sources (S) are separated.

7. Method for designing a logic circuitry, comprising the steps of:
providing a plurality of electronic units (EU) each comprising a first electronic component (EC1) for performing logic operations,
providing at least one second electronic component (EC2) in at least one of the plurality of electronic units (EU) for improving the soft-error sensitivity of the logic circuitry (LC);
selecting the second electronic component (EC2) such that the first and second electronic component (EC1, EC2) substantially implement the same logical function, and the second electronic component (EC2) being redundant; and
mutually coupling the outputs and the inputs of the first and second electronic component (EC1, EC2), respectively.
